(19) United States
(12) Patent Application Publication
(10) Pub. No.: US 2024/0162898 A1
(43) Pub. Date: May 16, 2024

(54) POWER SWITCH DEVICE WITH CASCODE STRUCTURE AND THE FORMING METHOD THEREOF

(71) Applicant: Monolithic Power Systems, Inc., San Jose, CA (US)

(72) Inventors: Vipin Pala, San Jose, CA (US); Panyin Liu, Chengdu (CN); Li Wang, Chengdu (CN); Qiang Fan, Chengdu (CN); Xiangyi Yang, Chengdu (CN)

(21) Appl. No.: 17/986,583

(22) Filed: Nov. 14, 2022

(51) Int. Cl. H03K 17/10; H03K 17/567

(52) U.S. Cl. CPC H03K 17/102; H03K 17/567; H03K 2017/6875

(57) ABSTRACT

A power switch device with cascode structure provides better performance with simple design. It has a normally-on device and a normally-off device coupled in series. A resistor is coupled to a control terminal of the normally-on device; and a capacitor is coupled between a control terminal of the normally-off device and the control terminal of the normally-on device.

### BACKGROUND OF THE INVENTION

In high voltage applications, MOSFETs are preferred due to their normally-off characteristic, which reduces power loss in the gate drive. However, MOSFETs have high parasitic capacitance, which brings high turn-on/turn-off loss in high voltage applications. As an alternative, silicon carbide (SiC) devices have much lower parasitic capacitance.

Junction field effect transistor (JFET) is a popular SiC device, which is typically combined with a metal oxide semiconductor field effect transistor (MOSFET) as a cascode structure in high voltage applications in recent years. As illustrated in FIG. 1, a typical cascode structure 100 is schematically shown. As shown in FIG. 1, the cascode structure comprises a JFET J1 and a MOSFET M1. The JFET J1 has its gate G_{J} connected to ground; and the MOSFET M1 has its gate G_{M} couple to a driver Dr. Typically, the JFET J1 is a high voltage normally-on device, while the MOSFET M1 is a low voltage normally-off device. The so called high voltage may refer to a voltage level higher than 100 volts; and the low voltage may refer to a voltage level lower than 100 volts. For example, the JFET J1 may sustain a voltage level of 1,700 volts; and the MOSFET M1 may have a breakdown voltage of 28 volts. The JFET J1 in FIG. 1 is in an ON state unless the gate-source voltage turns to a certain negative voltage. In high voltage applications, when the MOSFET M1 is turned OFF, the source voltage (i.e., the voltage at a source terminal S_{J}) of the JFET J1 goes high. Then, the gate-source voltage of the JFET J1 would go negative and reach a pinch-off voltage of the JFET, causing the JFET J1 to be OFF.

However, the turn-off speed of the JFET J1 is not under control. After the JFET J1's turn-off, the drain voltage (i.e., the voltage at a drain terminal D_{J}) of the JFET J1 will increase to hundreds of volts, even thousands of volts. Due to a parasitic capacitance C_{DSJ} between drain and source of the JFET J1, the drain voltage (i.e. the voltage at a drain terminal D_{M}) at the MOSFET M1 would be pulled to a very high voltage, resulting in a high spike. But the MOSFET M1 is typically a low voltage device, which normally operates at tens of volts.

Thus, efforts are needed to reduce this high spike to protect the MOSFET M1. In addition, the high turn-off speed of the JFET J1 brings electro-magnetic interference (EMI) problems, which is also a big issue.

### SUMMARY OF THE INVENTION

In accordance with an embodiment of the present invention, a power switch device with cascode structure is discussed. The power switch device comprises: a normally-on device and a normally-off device coupled in series between a first end and a second end. The normally-on device has a first terminal coupled to the first end, and a second terminal coupled to a first terminal DM of the normally-off device. The normally-off device further has a second terminal coupled to the second end. The normally-on device further has a control terminal coupled to the second end by way of a resistor. The normally-off device further has a control terminal coupled to the control terminal of the normally-on device by way of a capacitor. The control terminal of the normally-off device is further coupled to a driver, so as to be controlled ON and OFF by the driver.

In addition, in accordance with an embodiment of the present invention, a method for forming a cascode structure of a power switch device is discussed. The method comprises: coupling a first terminal of a normally-on device to a first end, a second terminal of the normally-on device to a first terminal of a normally-off device, and a second terminal of the normally-off device to a second end; coupling a control terminal of the normally-on device to the second end by way of a resistor; and coupling a control terminal of the normally-off device to a driver, and coupling the control terminal of the normally-off device to the control terminal of the normally-on device by way of a capacitor.

Furthermore, in accordance with an embodiment of the present invention, a power switch device with cascode structure is discussed. The power switch device includes: a normally-on device, a normally-off device, a resistor, and a capacitor. The normally-on device has a first terminal coupled to a first end. The normally-off device has a first terminal coupled to a second terminal of the normally-on device, and a second terminal coupled to a second end. The resistor is coupled between a control terminal of the normally-on device and the second terminal. The capacitor is coupled between a control terminal of the normally-off device and the control terminal of the normally-on device. The control terminal of the normally-off device is further coupled to a driver, so that the normally-off device is controlled ON and OFF by the driver.

### BRIEF DESCRIPTION OF DRAWINGS

FIG. 1 schematically shows a typically cascode structure 100 of a JFET and a MOSFET.

FIG. 2 schematically shows a cascode structure of a power switch device 200 in accordance with an embodiment of the present invention.

FIG. 3 schematically shows the cascode structure of the power switch device 200 coupled between a switch node and a reference ground in accordance with an embodiment of the present invention.

FIG. 4 schematically shows the cascode structure of the power switch device 200 coupled between a high voltage input terminal and a switch in accordance with an embodiment of the present invention.

FIG. 5 schematically shows a cascode structure of a power switch device 500 in accordance with an embodiment of the present invention.

FIG. 6 schematically shows a circuit configuration of the driver Dr in cascode structure of the power switch device 500 in accordance with an embodiment of the present invention.

FIG. 7 schematically shows a flowchart 700 of a method forming a cascode structure of a power switch device in accordance with an embodiment of the present invention.

The use of the similar reference label in different drawings indicates the same of like components.

### DETAILED DESCRIPTION OF THE INVENTION

Embodiments of circuits for power switch device are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

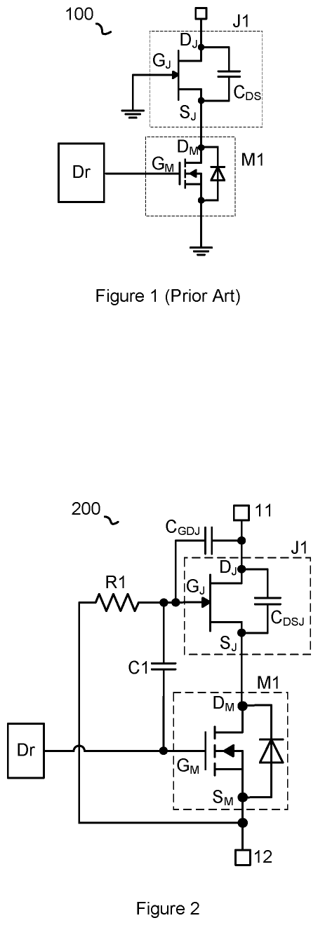

FIG. 2 schematically shows a cascode structure of a power switch device 200 in accordance with an embodiment of the present invention. In the example of FIG. 2, the power switch device 200 comprises: a normally-on device J1 and a normally-off device M1 coupled in series between a first end 11 and a second end 12. That is, the normally-on device J1 has a first terminal D_{J} coupled to the first end 11, and a second terminal S_{J} coupled to a first terminal D_{M} of the normally-off device M1; the normally-off device M2 further has a second terminal S_{M} coupled to the second end 12. The normally-on device J1 further has a control terminal G_{J} (e.g., gate) coupled to the second end 12 by way of a resistor R1. The normally-off device M1 further has a control terminal G M coupled to the control terminal of the normally-on device J1 by way of a capacitor C1. The control terminal of the normally-off device M1 is further coupled to a driver Dr, so as to be controlled ON and OFF by the driver Dr.

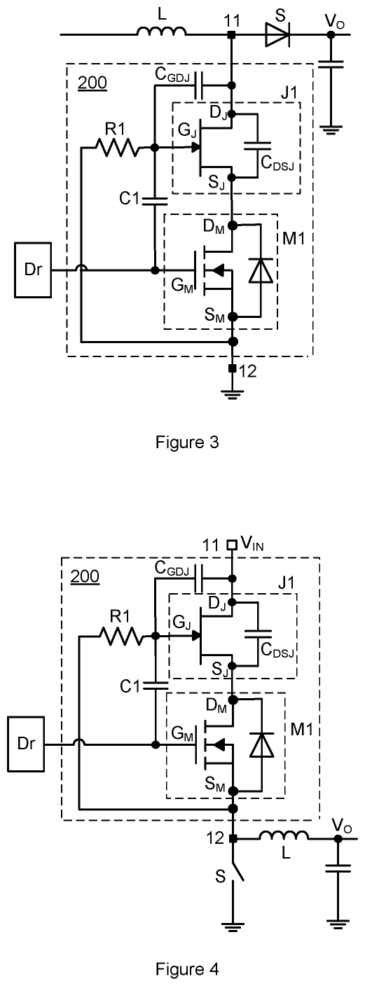

In one embodiment of the present invention, the first end 11 may be a switch node formed by a common connection of the cascode structure, a power device S, and an energy storage component L; and the second end 12 may be a reference ground, as shown in FIG. 3. In the example of FIG. 3, the power device S is shown as a power diode, and the energy storage component L is shown as an inductor. However, one skilled in the art should realize that the power device S may comprise a controllable switch, such as a MOSFET, an IGBT, or another cascode structure of JFET & MOSFET, etc. The energy storage component L may comprise other components, such as a transformer.

In other embodiments of the present invention, the first end 11 may be a high voltage input terminal, which is configured to receive an input voltage V_{IN} with a high voltage level (e.g., hundreds of volts or thousands of volts). The second end 12 may be a switch node formed by a common connection of the cascode structure 200, a power device S, and an energy storage component L, as shown in FIG. 4.

In one embodiment of the present invention, the resistor R1 may have a resistance value in the range of a few Ohms to a dozen of Ohms (e.g., from 1 Ohm to 19 Ohms), or a few Ohms to dozens of Ohms (e.g., from 1 Ohm to 99 Ohms); the capacitor C1 may have a capacitance value between the levels of pF (picofarad) to nF (nanofarad), e.g., the capacitance of the capacitor C1 may be from 1 pF to 1 nF. For example, C1 may have a capacitance of 220 pF, or it may be 0.1 nF.

In one embodiment of the present invention, the normally-on device J1 may comprise a JFET, such as a JFET formed by SiC; and the normally-off device M1 may comprise a MOSFET, such as a MOSFET formed by Silicon.

During the operation of the system, when the normally-off device M1 is turned off by the driver Dr, the voltage at the first end 11 increases. The increased voltage causes the voltage at the control terminal G_{J} of the normally-on device J1 to increase by way of a parasitic capacitance C_{GDJ} between drain D_{J} and gate G_{J} of the normally-on device J1. Then, the control terminal G_{M} of the normally-off device M1 also increases because of the capacitor C1. Accordingly, the normally-off device M1 would be turned on a little (i.e., the normally-off device M1 would operate at linear mode). Thus, the spike at the drain terminal D_{M} of the normally-off device (i.e., the common end of the normally-on device J1 and the normally-off device) and the turn-off speed of the normally-on device J1 are both clamped.

FIG. 5 schematically shows a cascode structure of a power switch device 500 in accordance with an embodiment of the present invention. The power switch device 500 in FIG. 5 is similar to the power switch device 200 in FIG. 2, with a difference that in the example of FIG. 5, the cascade structure further comprises a resistor R2 coupled in series with a capacitor C1 between the control terminal G_{J} of the normally-on device J1 and the control terminal G_{M} of the normally-off device M1.

In one embodiment of the present invention, the resistor R2 may have a resistance value in the range of a few Ohms to a dozen of Ohms, or a few Ohms to dozens of Ohms.

The operation of the power switch device 500 is similar to that of the power switch device 200 as discussed above. Compared with the power switch 200, the power switch device 500 brings further advantages. Due to the existence of a parasitic capacitance C_{GSM} between gate G M and source S M of the normally-off device M1, when the normally-off device M1 is turned off, the high voltage at the first end 11 would cause the parasitic capacitance C_{GDJ}, the capacitor C1, the resistor R2, and the parasitic capacitance C_{GSM} to form a current loop. Then, the resistor R2 performs an attenuation function in the current loop, which avoids a potential shoot through in the loop.

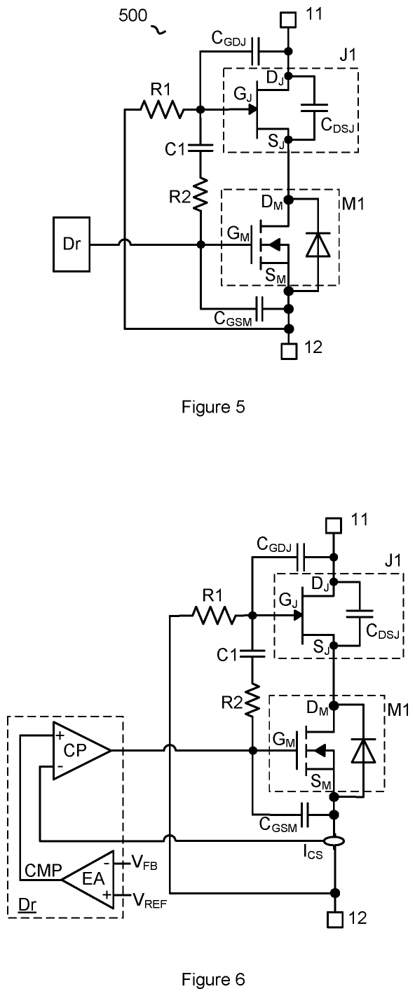

FIG. 6 schematically shows a circuit configuration of the driver Dr in accordance with an embodiment of the present invention. In the example of FIG. 6, the driver Dr comprises: an error amplifier EA, configured to amplify and integrate a difference between a feedback voltage indicative of an output voltage V_{O} (as shown the output voltage V_{O} at one end of the power device in FIG. 3 or the output voltage V_{O} at one end of the energy storage component in FIG. 4) and a reference voltage, to generate a compensation signal CMP; and a comparator CP, configured to compare a current sense signal I_{CS} indicative of a current flowing through the power switch device with the compensation signal CMP, to generate a control signal, which is used to control the normally-off device M1.

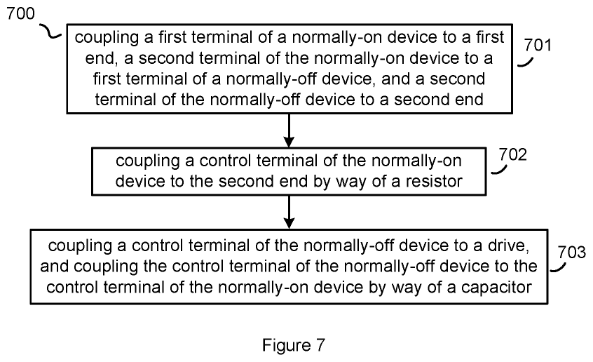

FIG. 7 schematically shows a flowchart 700 of a method for forming a cascode structure of a power switch device in accordance with an embodiment of the present invention. The method comprises:

Step 701, coupling a first terminal of a normally-on device to a first end, a second terminal of the normally-on device to a first terminal of a normally-off device, and a second terminal of the normally-off device to a second end.

Step 702, coupling a control terminal of the normally-on device to the second end by way of a resistor. And

Step 703, coupling a control terminal of the normally-off device to a driver, and coupling the control terminal of the normally-off device to the control terminal of the normally-on device by way of a capacitor.

In one embodiment of the present invention, the resistor between the control terminal of the normally-on device and the second terminal is a first resistor. The control terminal of the normally-off device is coupled to the control terminal of the normally-on device by way of the capacitor and a second resistor, and the second resistor is coupled in series with the capacitor.

In one embodiment, the first resistor and the second resistor may both have a resistance value in the range of a few Ohms to a dozen of Ohms, or a few Ohms to dozens of Ohms. The capacitor may have a capacitance value between the levels of pF to nF.

In one embodiment of the present invention, the power switch device is used in high voltage applications. The so-called high voltage may be with a voltage level of hundreds of volt or thousands of volt.

Several embodiments of the foregoing power switch device provide better performance with simple design. Unlike the conventional cascode structure, several embodiments of the foregoing cascode structure of the power switch device has a resistor coupled to the control terminal of the normally-on device, and has a capacitor (or a series coupled capacitor with a resistor) between the control terminal of the normally-on device and the control terminal of the normally-off device, to clamp the turn-off speed of the normally-off device and the spike at the common end of the normally-on device and the normally-off device. The capacitor (C1) has a low capacitance value, which is also called a low voltage capacitor. Thus, it can be implemented on a silicon die, and no co-package is needed. In addition, the resistor (R1, or the resistors R1 & R2) and the capacitor (C1) do not introduce additional power loss. Thus, the efficiency is not affected.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

1. A power switch device with cascode structure, comprising:
a normally-on device, having a first terminal coupled to a first end; and
a normally-off device, having a first terminal coupled to a second terminal of the normally-on device, and a second terminal coupled to a second end; wherein:
the normally-on device further has a control terminal coupled to the second end by way of a resistor;
the normally-off device further has a control terminal coupled to the control terminal of the normally-on device by way of a capacitor; and
the control terminal of the normally-off device is further coupled to a driver, so that the normally-off device is controlled ON and OFF by the driver.

2. The power switch device of claim 1, wherein:
the first end is a switch node formed by a common connection of the power switch device, a power device, and an energy storage component; and
the second end is a reference ground.

3. The power switch device of claim 1, wherein:
the first terminal is configured to receive an input voltage; and
the second terminal is a switch node formed by a common connection of the power switch device, a power device, and an energy storage component.

4. The power switch device of claim 1, wherein:
the resistor between the control terminal of the normally-on device and the control terminal of the second terminal is a first resistor, and wherein:
the control terminal of the normally-off device is coupled to the control terminal of the normally-on device by way of the capacitor and a second resistor, and the second resistor is coupled in series with the capacitor.

5. The power switch device of claim 1, wherein:
the normally-on device comprises a JFET; and
the normally-off device comprises a MOSFET.

6. A method for forming a cascode structure of a power switch device, comprising:
coupling a first terminal of a normally-on device to a first end, a second terminal of the normally-on device to a first terminal of a normally-off device, and a second terminal of the normally-off device to a second end;
coupling a control terminal of the normally-on device to the second end by way of a resistor; and
coupling a control terminal of the normally-off device to a driver, and coupling the control terminal of the normally-off device to the control terminal of the normally-on device by way of a capacitor.

7. The method of claim 6, wherein:
the resistor between the control terminal of the normally-on device and the control terminal of the second terminal is a first resistor;
the control terminal of the normally-off device is coupled to the control terminal of the normally-on device by way of the capacitor and a second resistor; and
the second resistor is coupled in series with the capacitor.

8. The method of claim 6, wherein:
the first terminal is a switch node formed by a common connection of the power switch device, a power device, and an energy storage component; and
the second terminal is a reference ground.

9. The method of claim 6, wherein:
the first terminal is configured to receive an input voltage; and
the second terminal is a switch node formed by a common connection of the power switch device, a power device, and an energy storage component.

10. The method of claim 6, wherein:
the first terminal is a switch node formed by a common connection of the power switch device, a power device, and an energy storage component; and
the second end is a reference ground.

11. A power switch device with cascode structure, comprising:
a normally-on device, having a first terminal coupled to a first end;
a normally-off device, having a first terminal coupled to a second terminal of the normally-on device, and a second terminal coupled to a second end;
a resistor, coupled between a control terminal of the normally-on device and the second terminal; and
a capacitor, coupled between a control terminal of the normally-off device and the control terminal of the normally-on device; wherein:
the control terminal of the normally-off device is further coupled to a driver, so that the normally-off device is controlled ON and OFF by the driver.

12. The power switch device of claim 11, wherein:
the first terminal is a switch node formed by a common connection of the power switch device, a power device, and an energy storage component; and
the second terminal is a reference ground.

13. The power switch device of claim 11, wherein:
the first terminal is configured to receive an input voltage; and
the second terminal is a switch node formed by a common connection of the power switch device, a power device, and an energy storage component.

14. The power switch device of claim 11, wherein:
the resistor between the control terminal of the normally-on device and the control terminal of the second terminal is a first resistor, and wherein the power switch device further comprises:
a second resistor, coupled in series with the capacitor, wherein the control terminal of the normally-off device is coupled to the control terminal of the normally-on device by way of the capacitor and the second resistor.

15. The power switch device of claim 11, wherein:
the normally-on device comprises a JFET; and
the normally-off device comprises a MOSFET.
